(19) United States
(12) Patent Application Publication
(10) Pub. No.: US 2025/0385233 A1
(43) Pub. Date: Dec. 18, 2025

(54) SEMICONDUCTOR PACKAGE

(71) Applicant: Samsung Electronics Co., Ltd., Suwon-si (KR)

(72) Inventor: Sehyeon PARK, Suwon-si (KR)

(21) Appl. No.: 18/966,682

(22) Filed: Dec. 3, 2024

(30) Foreign Application Priority Data
Jun. 13, 2024 (KR) 10-2024-0077043

(51) Int. Cl. H01L 25/18; H01L 21/48; H01L 21/56; H01L 23/00; H01L 23/18; H01L 23/31; H01L 23/498; H10B 80/00

(52) U.S. Cl. CPC H01L 25/18; H01L 23/3128; H01L 23/49833; H01L 23/49838; H01L 24/16; H01L 24/32; H01L 24/48; H01L 24/73; H01L 21/4853; H01L 21/565; H01L 23/18; H01L 24/49; H01L 2224/16227; H01L 2224/32225; H01L 2224/48091; H01L 2224/48227; H01L 2224/4903; H01L 2224/49175; H01L 2224/73204; H01L 2224/73265; H01L 2225/0651; H01L 2225/06562; H01L 2924/1431; H10B 80/00

(57) ABSTRACT

A semiconductor package includes a lower package, and a substrate on the lower package, wherein the lower package comprises a lower package substrate, a first semiconductor chip on the lower package substrate such that a front side of the first semiconductor chip on which a first chip pad is formed faces the lower package substrate, a second semiconductor chip on a lower surface of the substrate and spaced apart from the first semiconductor chip in a first direction perpendicular to an upper surface of the lower package substrate, and a vertical wire connecting the lower package substrate and the second semiconductor chip in the first direction.

### CROSS-REFERENCE TO RELATED APPLICATION

This application claims priority to Korean Patent Application No. 10-2024-0077043, filed on Jun. 13, 2024, in the Korean Intellectual Property Office, the entire contents of which are hereby incorporated by reference.

### BACKGROUND

### Field

The present disclosure relates to a semiconductor package.

### Description of Related Art

A package on package (POP) may include an upper package stacked on a lower package to save space on a system board and reduce the size of a portable electronic device.

If an application processor (AP) and a modem are each manufactured with one system on chip (SOC), a modem system in package (SIP) may have to be additionally mounted on the system board. In this case, the size of the system board is increased, thus making the battery size smaller. To solve this problem, a package-on package that does not increase the mounting area of the system board is being developed.

### SUMMARY

To solve one or more problems (e.g., the problems described above and/or other problems not explicitly described herein), the present disclosure provides a semiconductor package with improved integration density.

To solve one or more problems (e.g., the problems described above and/or other problems not explicitly described herein), the present disclosure provides a semiconductor package with improved mechanical reliability.

To solve one or more problems (e.g., the problems described above and/or other problems not explicitly described herein), the present disclosure provides a semiconductor package with improved electrical performance.

According to some embodiments of the present disclosure for solving the above technical problems, a semiconductor package may include a lower package, and a substrate on the lower package, wherein the lower package comprises a lower package substrate, a first semiconductor chip on the lower package substrate such that a front side of the first semiconductor chip on which a first chip pad is formed faces the lower package substrate, a second semiconductor chip on a lower surface of the substrate and spaced apart from the first semiconductor chip in a first direction perpendicular to an upper surface of the lower package substrate, and a vertical wire connecting the lower package substrate and the second semiconductor chip in the first direction.

According to some embodiments of the present disclosure for solving the above technical problems, a semiconductor package may include a lower package, an upper package on the lower package, and an interposer substrate between the lower package and the upper package, wherein the lower package includes a lower package substrate, a first semiconductor chip on the lower package substrate such that a front side of the first semiconductor chip on which a first chip pad is formed faces the lower package substrate, a second semiconductor chip spaced upward from the first semiconductor chip such that a front side of the second semiconductor chip on which a second chip pad is formed faces the lower package substrate, and a vertical wire extending in a vertical direction to electrically connect the lower package substrate and the second chip pad, and the upper package includes an upper package substrate, a connection terminal connecting the upper package substrate and the interposer substrate, and an upper semiconductor chip electrically connected to the upper package substrate on the upper package substrate.

According to some embodiments of the present disclosure for solving the above technical problems, a semiconductor package may include a lower package, an upper package on the lower package, and an interposer substrate between the lower package and the upper package, wherein the lower package includes a lower package substrate, a modem chip on the lower package substrate such that a front side of the modem chip on which a modem chip pad is formed faces the lower package substrate, a conductive post electrically connecting the lower package substrate and the interposer substrate on one side of the modem chip, a solder bump electrically connecting the modem chip pad and the lower package substrate, a volatile memory chip attached onto the lower surface of the interposer substrate such that a front side of the volatile memory chip on which a memory chip pad is formed faces the lower package substrate, and spaced apart from the modem chip in a vertical direction perpendicular to an upper surface of the lower package substrate, a vertical wire extending in the vertical direction to electrically connect the lower package substrate and the memory chip pad, and a lower mold layer at least partially covering the modem chip, the volatile memory chip, the conductive post, and the vertical wire on the lower package substrate, and the upper package includes an upper package substrate, a nonvolatile memory chip electrically connected to the upper package substrate on the upper package substrate, and an upper mold layer at least partially covering the nonvolatile memory chip on the upper package substrate.

According to some aspects of the present disclosure, the integration density of the semiconductor package may be improved.

According to some aspects of the present disclosure, the mechanical reliability of the semiconductor package may be improved.

According to some aspects of the present disclosure, the electrical performance of the semiconductor package may be improved.

### BRIEF DESCRIPTION OF THE DRAWINGS

FIG. 1 is a diagram illustrating a semiconductor package according to some embodiments of the present disclosure.

FIGS. 2 to 9 are diagrams illustrating a method for manufacturing a semiconductor package according to some embodiments of the present disclosure.

FIG. 10 is a diagram illustrating a semiconductor package.

FIGS. 11 to 14 are diagrams illustrating a method for manufacturing a semiconductor package according to some embodiments of the present disclosure.

FIG. 15 is a diagram illustrating a semiconductor package according to some embodiments of the present disclosure.

FIGS. 16 to 19 are diagrams illustrating a method for manufacturing a semiconductor package according to some embodiments of the present disclosure.

FIG. 20 is a diagram illustrating a semiconductor package according to some embodiments of the present disclosure.

FIG. 21 is a diagram illustrating a semiconductor package according to some embodiments of the present disclosure.

FIG. 22 is a diagram illustrating a semiconductor package according to some embodiments of the present disclosure.

### DETAILED DESCRIPTION

Hereinafter, example embodiments of the present disclosure will be described in more detail with reference to the attached drawings. The same reference numerals are used for the same components in the drawings, and duplicate descriptions for the same components are omitted. As used herein, the term “and/or” includes any and all combinations of one or more of the associated listed items. It will be understood that when an element is referred to as being “on,” “attached” to, “connected” to, “coupled” with, “contacting,” etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. It will be understood that, although the terms “first”, “second”, etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure. It is noted that aspects described with respect to one embodiment may be incorporated in different embodiments although not specifically described relative thereto. That is, all embodiments and/or features of any embodiments can be combined in any way and/or combination.

A semiconductor package according to some embodiments of the present disclosure will be described in detail with reference to the drawings.

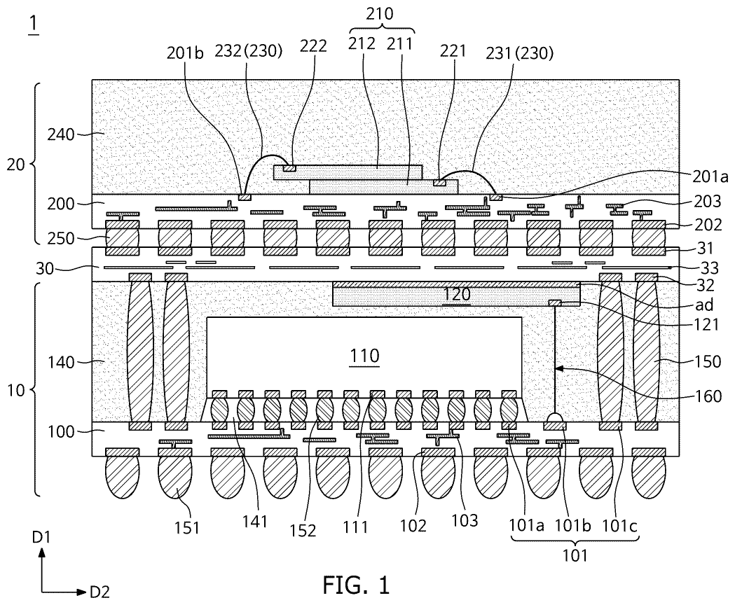

FIG. 1 is a diagram illustrating a semiconductor package according to some embodiments of the present disclosure.

Referring to FIG. 1, the semiconductor package 1 may include a lower package 10, an upper package 20, and a substrate disposed between the lower package 10 and the upper package 20.

The substrate may include an interposer substrate 30, a printed circuit board (not illustrated), etc. for electrically connecting the lower package 10 and the upper package 20. In the semiconductor package described below, it is assumed that the substrate is the interposer substrate 30.

An up-down direction or a vertical direction as used herein may be a first direction D1 perpendicular to an upper surface of the lower package substrate 100. In addition, a left-right direction or a horizontal direction as used herein may be a second direction D2 parallel to the upper surface of the lower package substrate 100. It will be understood that such directional indicators are not limiting and intended to encompass different orientations of the device in use or operation in addition to the orientation depicted in the figures or implied by the directional indicator. For example, if the device in the figures is turned over, elements described as “below” or “beneath” other elements or features would then be oriented “above” the other elements or features.

The lower package 10 may include a lower package substrate 100 and a first semiconductor chip 110 disposed on the lower package substrate 100.

The lower package substrate 100 may be a printed circuit board (PCB) or a redistributed layer (RDL). In some embodiments, the printed circuit board may be a multilayer printed circuit board having a substrate base formed by stacking a plurality of base layers. In some embodiments, each of the plurality of base layers forming the substrate base may be formed of at least one material selected from phenol resin, epoxy resin, or polyimide. For example, each of the plurality of base layers of the substrate base may include at least one material selected from frame retardant 4 (FR4), tetrafunctional epoxy, polyphenylene ether, epoxy/polyphenylene oxide, bismaleimide triazine (BT), thermount, cyanate ester, polyimide, or liquid crystal polymer.

The lower package substrate 100 may include a wiring pattern 103. The wiring pattern 103 may be disposed on an upper surface and a lower surface of each of a plurality of base layers. For example, the wiring pattern 103 may include an electrolytically deposited (ED) copper foil, a rolled-animated (RA) copper foil, a stainless steel foil, an aluminum foil, ultra-thin copper foils, sputtered copper, copper alloys, etc. A conductive via may electrically connect the wiring patterns 103. The conductive via may be formed to penetrate through at least one of the plurality of base layers. In some embodiments, the conductive via may be formed of copper, nickel, stainless steel, or beryllium copper.

The lower package substrate 100 may include a plurality of upper pads 101 to be electrically connected to the first semiconductor chip 110, a second semiconductor chip 120, a plurality of external pads 102, and a vertical connection member 150. The plurality of upper pads 101 may be formed on one side of the lower package substrate 100. The plurality of external pads 102 may be formed on the other side of the lower package substrate 100.

The plurality of upper pads 101 may include a first upper pad 101a electrically connected to the first semiconductor chip 110, a second upper pad 101b electrically connected to the second semiconductor chip 120, and a third upper pad 101c electrically connected to the vertical connection member 150.

The first semiconductor chip 110 may include a first chip pad 111 to be connected to the first upper pad 101a. The second semiconductor chip 120 may include a second chip pad 121 to be connected to the second upper pad 101b. The first semiconductor chip 110 may be disposed such that its front side on which the first chip pad 111 is formed faces the lower package substrate 100. The second semiconductor chip 120 may be disposed such that its front side on which the second chip pad 121 is formed faces the lower package substrate 100. That is, the first chip pad 111 and the second chip pad 121 may be disposed to face the first upper pad 101a and the second upper pad 101b, respectively. The second upper pad 101b and the second chip pad 121 may be aligned in the first direction D1 to be connected to each other through a vertical wire 160 to be described below.

The first upper pad 101a may be connected to the first semiconductor chip 110, and the second upper pad 101b may be connected to the second semiconductor chip 120. Specifically, the first upper pad 101a may be connected to the first chip pad 111 of the first semiconductor chip 110, and the second upper pad 101b may be connected to the second chip pad 101b of the second semiconductor chip 120. The first upper pad 101a may transmit and receive data signals between the first semiconductor chip 110 and the lower package substrate 100, and the second upper pad 101b may transmit and receive data signals between the second semiconductor chip 120 and the lower package substrate 100. The first upper pad 101a and the second upper pad 101b may transmit and receive the data signals between the first semiconductor chip 110 and the second semiconductor chip 120 through the wiring pattern 103 implemented inside the lower package substrate 100.

The lower package 10 may include a solder bump 152 disposed on the lower package substrate 100. The first semiconductor chip 110 may be attached to the lower package substrate 100 with a flip-chip method. The first semiconductor chip 110 may be attached to the lower package substrate 100 through the solder bump 152 formed on the first chip pad 111.

A plurality of external terminals 151 may be formed on the plurality of external pads 102 formed on the lower package substrate 100. The plurality of external terminals 151 may be formed on each of the plurality of external pads 102. The lower package substrate 100 may be mounted on a system board. That is, the external terminal 151 of the lower package substrate 100 may be electrically connected to a pad of the system board.

The lower package 10 may include an underfill 141. The underfill 141 may include an underfill resin such as an epoxy resin, a silica filler, or a flux. The underfill 141 may be formed by a capillary underfill (CUF) process or a molded underfill process. The underfill 141 formed by the molded underfill (MUF) may be integrated with a lower mold layer 140 to be described below.

The underfill 141 may be on and at least partially cover the solder bump 152. The underfill 141 may at least partially fill a space between the first semiconductor chip 110 and the lower package substrate 100. The adhesive strength between the first semiconductor chip 110 and the lower package substrate 100 may be increased by the underfill 141.

In addition, the underfill 141 may allow other components such as the first semiconductor chip 110, the lower package substrate 100, the solder bump 152, etc. to counteract the deterioration of physical strength due to deformation. For example, the underfill 141 may be a portion configured to remove a space where foreign substances or moisture may penetrate and to prevent electrical migration.

In some embodiments, the first semiconductor chip 110 may include an integrated circuit (IC), a system on chip (SoC), an application processor (AP), a mobile AP, a chipset, or a set of chips. In some embodiments, the first semiconductor chip 110 may include a central processing unit (CPU), a graphics processing unit (GPU), and/or a modem. For example, the first semiconductor chip 110 may be implemented as a modem die, or as a modem die that supports a Wideband Code Division Multiple Access (WCDMA) communication method, but embodiments are not limited thereto.

The second semiconductor chip 120 may be disposed on a lower surface of the interposer substrate 30. The second semiconductor chip 120 may be attached to the interposer substrate 30 through an adhesive member (ad). Since the second semiconductor chip 120 is disposed on the lower surface of the interposer substrate 30 rather than the lower package substrate 100, only the first semiconductor chip 110 may be disposed on the lower package substrate 100.

The lower package 10 illustrated in FIG. 1 may be implemented as a system in package (SiP), but embodiments are not limited thereto.

According to some embodiments, the semiconductor chips 110 and 120 may include a plurality of materials having different coefficients of thermal expansion (CTE). Warpage may occur in the semiconductor chips 110 and 120 during high temperature process such as a reflow process, etc. or cooling to room temperature. According to a comparative example, if different types of semiconductor chips are mounted on the lower package substrate 100, different warpage patterns may occur and it may be difficult to predict or control the overall warpage. On the other hand, in the semiconductor package 1 according to an example of the disclosure, one semiconductor chip or one type of semiconductor chip is mounted on the lower package 10 and accordingly, the warpage pattern may be predicted and calculated relatively easily. Furthermore, in the design of the semiconductor package 1, the overall pattern or degree of warpage may be predicted and reflected.

According to some embodiments, at least a portion of the second semiconductor chip 120 may be disposed to overlap the first semiconductor chip 110 in the up-down direction. Since the portion of the second semiconductor chip 120 overlaps the first semiconductor chip 110, the area of the lower package 10 in the horizontal direction may be reduced. Accordingly, the lower package substrate 100 having a relatively small area may be used for the lower package 10, thereby reducing manufacturing costs.

In addition, according to some aspects, other semiconductor chips or semiconductor packages may be mounted on the system board in addition to the semiconductor package 1. Since the mounting area of the semiconductor package 1 on the system board is reduced, the types of semiconductor chips or semiconductor packages that can be mounted on the system board may be diversified and the number thereof may increase. Accordingly, the system board mounted with the semiconductor package 1 according to an example of the present disclosure may have more diverse functions and improved performance. In addition, a designer of the system board may acquire an increased degree of design freedom.

The lower package 10 may include the vertical wire 160 connecting the lower package substrate 100 and the second semiconductor chip 120 in the first direction D1. The vertical wire 160 may be formed by a wire bonding process. The vertical wire 160 may include nickel (Ni), antimony (Sb), bismuth (Bi), zinc (Zn), indium (In), palladium (Pd), platinum (Pt), aluminum (Al), copper (Cu), molybdenum (Mo), titanium (Ti), gold (Au), silver (Ag), chromium (Cr), tin (Sn), etc.

The second semiconductor chip 120 may be electrically connected to the lower package substrate 100 through the vertical wire 160. The vertical wire 160 may extend in the first direction D1. That is, the vertical wire 160 may form an angle of approximately 90 degrees with the upper surface of the lower package substrate 100. The vertical wire 160 may be disposed on one side of the first semiconductor chip 110.

The term “vertical” or “up-down” as used herein may refer to forming an angle of 90 degrees with a reference surface such as the upper surface of the lower package substrate 100 and may also include a slight difference in angle or direction. Additionally, even if the vertical wire 160 is deformed, it can be said that the vertical wire 160 is connected vertically or in the vertical direction as long as the overall structure is maintained vertically or in the up-down direction.

The second semiconductor chip 120 may be spaced apart from the first semiconductor chip 110 in the up-down direction. The second semiconductor chip 120 may be spaced upward from the upper surface of the first semiconductor chip 110. That is, a portion of the lower mold layer 140 may be disposed between the second semiconductor chip 120 and the first semiconductor chip 110.

A lower surface of the second semiconductor chip 120 may be spaced upward from the upper surface of the first semiconductor chip 110. In other words, the vertical wire 160 may have a length greater than a thickness of the first semiconductor chip 110. If the temperature of the semiconductor chip rises above a certain temperature, the performance of the semiconductor chip may deteriorate. Because the second semiconductor chip 120 is spaced upward from the first semiconductor chip 110, it is possible to prevent heat generated from the first semiconductor chip 110 from being transferred to the second semiconductor chip 120 excessively. In other words, the distance between the first semiconductor chip 110 and the second semiconductor chip 120 may serve as a thermal buffer. Because the second semiconductor chip 120 has the vertical arrangement relationship with respect to the first semiconductor chip 110 as described above, it is possible to prevent performance degradation of the second semiconductor chip 120.

The first semiconductor chip 110 and the second semiconductor chip 120 may be deformed due to thermal expansion, etc. under certain conditions. Because the first semiconductor chip 110 and the second semiconductor chip 120 are arranged to be spaced apart from each other, it is possible to prevent friction between the chips even if deformation occurs due to thermal expansion, etc. That is, damages to the first semiconductor chip 110 and the second semiconductor chip 120 due to mutual friction may be prevented.

The second chip pad 121 of the second semiconductor chip 120 may be at least partially exposed from the first semiconductor chip 110. The second semiconductor chip pad 121 may be disposed not to overlap the first semiconductor chip 110 in the first direction D1. That is, the first semiconductor chip 110 may not be disposed between the second chip pad 121 and the lower package substrate 100.

The vertical wire 160 may connect the second chip pad 121 of the second semiconductor chip 120 and the second upper pad 101b of the lower package substrate 100 in the first direction D1. In order for the vertical wire 160 to vertically connect the second chip pad 121 and the second upper pad 101b of the lower package substrate 100, interference with the first semiconductor chip 110 may be prevented. Accordingly, the second semiconductor chip 120 is disposed such that at least a portion of the second chip pad 120 overlaps the first semiconductor chip 110 in the first direction D1, while the second chip pad 121 of the second semiconductor chip 120 does not overlap the first semiconductor chip 110 in the first direction D1. In other words, the second semiconductor chip 120 may be disposed to be offset from the first semiconductor chip 110 in the second direction D2. The second semiconductor chip 120 may be disposed to be offset from the first semiconductor chip 110 in the horizontal direction such that the second chip pad 121 corresponds to the second upper pad 101b of the lower package substrate 100 in the vertical direction.

According to the comparative example, the second semiconductor chip 120 may be connected to the interposer substrate 30 through a connection terminal such as a solder bump, etc. On the other hand, the second semiconductor chip 120 according to an example of the disclosure is not electrically connected to the interposer substrate 30 but connected to the lower package substrate 100 through the vertical wire 160. In this case, compared to the comparative example with the connection through the interposer substrate 30, the signal transmission distance between the second semiconductor chip 120 and the lower package substrate 100 may be shortened. Accordingly, the second semiconductor chip 120 according to the example of the present disclosure may have excellent electrical performance compared to the comparative example.

According to the comparative example, the second semiconductor chip 120 may be electrically connected to the interposer substrate 30 through wire bonding. On the other hand, the second semiconductor chip 120 may be connected to the lower package substrate 100 through the vertical wire 160. In this case, a relatively smaller amount of wire may be used compared to the comparative example. Accordingly, with the vertical wire 160, a reduced amount of material may be used compared to the comparative example and manufacturing costs may be reduced. In addition, compared to the comparative example, the vertical wire 160 may prevent connection failure thereby improving the defect rate.

The vertical connection member 150 electrically connecting the lower package substrate 100 and the interposer substrate 30 may be disposed on the lower package substrate 100. There may be a plurality of vertical connection members 150 disposed in the second direction D2. The vertical connection member 150 may extend in the first direction D1 perpendicular to the upper surface of the lower package substrate 100. The vertical connection member 150 may be a through mold via (TMV), a conductive pillar, or at least one conductive bump.

The vertical connection member 150 may electrically connect the interposer substrate 30 and the lower package substrate 100. The vertical connection member 150 may be connected to the third upper pad 101c of the lower package substrate 100. An upper semiconductor chip 210 mounted on the upper package 20 and the lower package substrate 100 may be electrically connected to each other through the vertical connection member 150. The third upper pad 101c may transmit and receive the data signals between the upper semiconductor chips 210 through the wiring pattern 103 implemented inside the lower package substrate 100.

The lower package 10 may include the lower mold layer 140 at least partially covering the first semiconductor chip 110, the second semiconductor chip 120, and the vertical connection member 150. The lower mold layer 140 on the lower package substrate 100 may be on and at least partially cover the first semiconductor chip 110, the second semiconductor chip 120, and the vertical wire 160. Specifically, the lower mold layer 140 may be on and at least partially cover side surfaces and the upper surface of the first semiconductor chip 110, side surfaces and the lower surface of the second semiconductor chip 120, side surfaces of the vertical connection member 150, and the vertical wire 160. In addition, the lower mold layer 140 may cover the upper surface of the lower package substrate 100 and side surfaces of the underfill 141. In some embodiments, the lower mold layer 140 may be formed through the MUF process, and the lower mold layer 140 may be on and at least partially cover side surfaces and upper and lower surfaces of the first semiconductor chip 110.

The lower mold layer 140 may include an epoxy molding compound (EMC). However, embodiments are not limited thereto, and the lower mold layer 140 may include various materials such as epoxy-based materials, thermosetting materials, thermoplastic materials, UV-treated materials, etc.

The lower package substrate 100 may be a substrate for connecting the first semiconductor chip 110 and the second semiconductor chip 120 of the lower package 10, and the upper package 20 to an external device.

The plurality of external terminals 151 for connection to the external device may be attached to a lower portion of the lower package substrate 100. Specifically, the plurality of external terminals 151 may be attached to the external pad 102. The semiconductor package 1 may be electrically connected to the external device through the plurality of external terminals 151. The first semiconductor chip 110 and the second semiconductor chip 120 mounted on the lower package 10, and the upper semiconductor chip 210 mounted on the upper package 20 may be electrically connected to the external device.

The upper package 20 includes an upper package substrate 200, the upper semiconductor chip 210 mounted on the upper package substrate 200, a wire 230 electrically connecting the upper semiconductor chip 210 and the upper package substrate 200, and a connection terminal 250 electrically connecting the upper package substrate 200 and the interposer substrate 30.

The upper package substrate 200 may include upper pads 201a and 201b electrically connected to the upper semiconductor chip 210, a lower pad 202 in contact with the connection terminal 250, and a wiring pattern 203 electrically connecting the upper pad 201 and the lower pad 202. The upper semiconductor chip 210 mounted on the upper package 20 may exchange signals with the interposer substrate 30 through the connection terminal 250. The description of the upper package substrate 200 may be the same as that of the lower package substrate 100.

The upper semiconductor chip 210 may be disposed on an upper surface of the upper package substrate 200. Alternatively, the upper semiconductor chip 210 may be attached to the upper surface of the upper package substrate 200 with an adhesive member.

The upper package 20 may include a plurality of upper semiconductor chips 211 and 212. The upper package 20 may include a first upper semiconductor chip 211 and a second upper semiconductor chip 212. Although FIG. 1 illustrates two upper semiconductor chips 211 and 212, aspects are not limited thereto, and one or three or more semiconductor chips may be provided.

The upper semiconductor chips 211 and 212 may each include a first upper chip pad 221 and a second upper chip pad 222. The upper chip pads 221 and 222 may each be electrically connected to the upper pads 201a and 201b of the upper package substrate 200. The first upper semiconductor chip 211 and the second upper semiconductor chip 212 may each be connected to the upper pads 201a and 201b through a first upper wire 231 and a second upper wire 232.

The upper semiconductor chips 211 and 212 may be offset-stacked on the upper package substrate 200. The second upper semiconductor chip 212 may be disposed to at least partially expose the first upper chip pad 221. However, embodiments are not limited thereto, and the upper semiconductor chips 211 and 212 may be disposed side by side or stacked on top of each other on the upper package substrate 200. The arrangement of the upper semiconductor chips 211 and 212 is not limited thereto, and various arrangements are possible.

The upper semiconductor chip 210 may include a nonvolatile memory device. The non-volatile memory device include at least one of an electrically erasable programmable read-only memory (EEPROM), a flash memory, a magnetic random access memory (MRAM), a spin-transfer torque MRAM (STT-MRAM), a ferroelectric RAM (FeRAM), a phase change memory (PRAM), a resistive RAM (RRAM), a nanotube RRAM, a polymer RAM (PoRAM), a nano floating gate memory (NFGM), a holographic memory, a molecular electronics memory device, or an insulator resistance change memory, but is not limited thereto.

The upper semiconductor chip 210 may include a volatile memory device. The volatile memory device may be a random access memory (RAM), a dynamic RAM (DRAM), or a static RAM (SRAM), but is not limited thereto.

The connection terminal 250 may electrically connect the upper package substrate 200 and the interposer substrate 30. The connection terminal 250 may connect the lower pad 202 of the upper package substrate 200 and the upper pad 31 of the interposer substrate 30.

The upper package 20 may include an upper mold layer 240 on the upper package substrate 200, which may be on and at least partially cover the upper semiconductor chip 210 and the upper wire 230. Specifically, the upper mold layer 240 may be on and at least partially cover side surfaces and an upper surface of the upper semiconductor chip 210 and the upper wire 230. The description of the upper mold layer 240 may be the same as that of the description of the lower mold layer 140.

The semiconductor package 1 may include the interposer substrate 30 disposed between the lower package 10 and the upper package 20. The interposer substrate 30 may be a printed circuit board (PCB) or a redistributed layer (RDL). The interposer substrate 30 may be disposed on the lower mold layer 140 of the lower package 10.

The interposer substrate 30 may include an upper pad 31 to which the connection terminal 250 of the upper package 20 is connected, and a lower pad 32 to which the vertical connection member 150 of the lower package 10 is connected. The upper pad 31 may be formed on the upper surface of the interposer substrate 30, and the lower pad 32 may be formed on the lower surface of the interposer substrate 30. The interposer substrate 30 may electrically connect the upper package 20 and the lower package 10.

The interposer substrate 30 may include a wiring pattern 33 electrically connecting the upper pad 31 and the lower pad 32. That is, the interposer substrate 30 may electrically connect the upper semiconductor chip 210 mounted on the upper package 20 and the lower package substrate 100. The data signal and/or the control signal of the upper semiconductor chip 210 may be transmitted and received to and from an external device through the vertical connection member 150.

According to some embodiments, the area of the upper package 20 may be equal to or smaller than the area of the lower package 10. If the area of the lower package 10 decreases, the area of the upper package 20 may also decrease. The lower package 10 may include the first semiconductor chip 110 and the second semiconductor chip 120 partially overlapping each other, which may reduce the mounting area. As a result, the area of the upper package 20 and the area of the interposer substrate 30 connecting the upper package 20 and the lower package 10 may be reduced. Therefore, the interposer substrate 30 and the upper package 20 having a relatively small area may be used, and the manufacturing costs may be reduced.

Although FIG. 1 illustrates an example in which the lower package 10 and the upper package 20 have different structures, aspects are not limited thereto. For example, the structure of the lower package 10 may also be applied to the upper package 20.

In addition, although it is described above that the semiconductor package 1 has a package on package (POP) structure in which the upper package 20 and the lower package 10 are stacked, aspects are not limited thereto. The technical idea of the present disclosure may also be applied to a semiconductor package in which the upper package 20 is not included. For example, it may be a semiconductor package including only the lower package 10, and it may include a metal layer or an insulating layer instead of the interposer substrate 30.

Hereinafter, a method for manufacturing the semiconductor package 1 according to some embodiments will be described in detail.

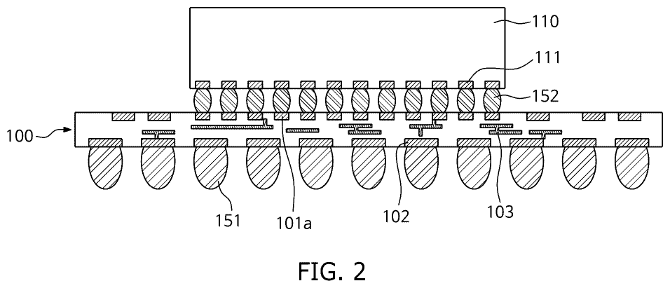

FIGS. 2 to 9 are diagrams illustrating a method for manufacturing a semiconductor package according to some embodiments of the present disclosure.

With reference to FIGS. 2 to 6, the method for manufacturing the semiconductor package according to some embodiments may include manufacturing the lower package 10 which will be described below.

The manufacturing the lower package 10 may include placing the first semiconductor chip 110 on the lower package substrate 100. The first semiconductor chip 110 may be disposed such that its front side on which the first chip pad 111 is formed faces the lower package substrate 100. The solder bump 152 may be formed on the first chip pad 111 of the first semiconductor chip 110. The first semiconductor chip 110 may be mounted on the lower package substrate 100 using a flip chip method. That is, the solder bump 152 formed on the first semiconductor chip 110 may be in contact with the first upper pad 101a of the lower package substrate 100.

A reflow process or a thermocompression process may be performed while the solder bump 152 of the first semiconductor chip 110 is in contact with the first upper pad 101a. The solder bump 152 may be fused at a high temperature to mechanically and electrically connect the first semiconductor chip 110 to the lower package substrate 100.

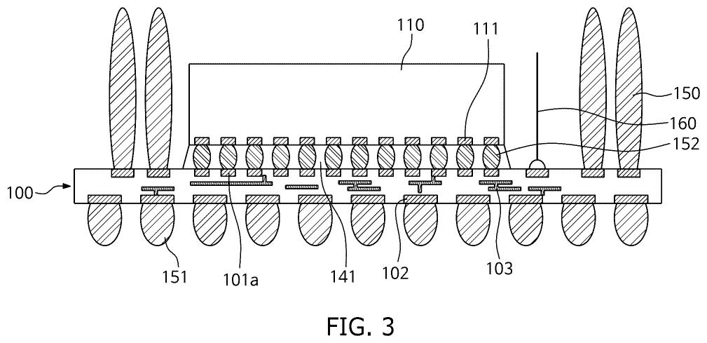

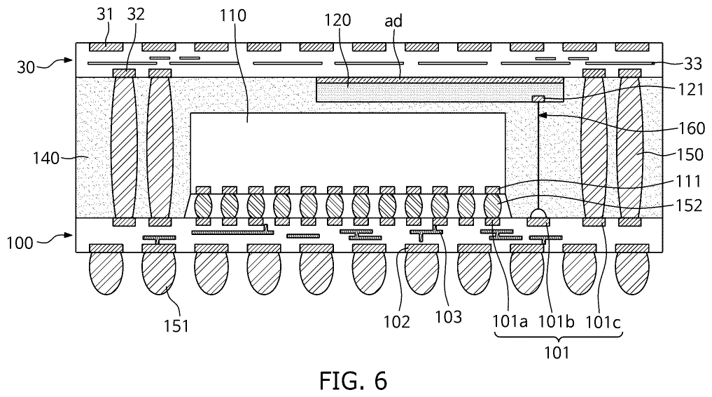

The underfill 141 may be disposed between the first semiconductor chip 110 and the lower package substrate 100. The underfill 141 may be formed by a capillary underfill (CUF) process. The underfill 141 may be formed before the solder bump 152 is fused or may be formed after the solder bump 152 is fused. In addition, the underfill 141 may be formed by molded underfill (MUF). In this case, the underfill 141 may be formed of the same material as that of the lower mold layer 140 (refer to FIG. 6). In FIG. 3, the underfill 141 is illustrated to be formed by CUF, but this is only an example.

Referring to FIG. 3, the manufacturing the lower package 10 may include forming the vertical connection member 150 on the lower package substrate 100. The vertical connection member 150 may extend along the first direction D1. The vertical connection member 150 may be formed of copper (Cu). However, embodiments are not limited thereto, and the vertical connection member 150 may include other conductive metals.

The vertical connection member 150 may be a conductive post. However, embodiments are not limited thereto and the vertical connection member 150 may be formed by wire bonding, solder balls, etc.

The vertical wire 160 may be formed on the lower package substrate 100. The vertical wire 160 may be formed using a capillary. The vertical wire 160 may extend upward from the second upper pad 101b. The vertical wire 160 may have a smaller height than the vertical connection member 150. The vertical wire 160 may have a height equal to the height of the vertical connection member 150 minus the thickness of the second semiconductor chip 120. That is, while placing the interposer substrate 30 with the second semiconductor chip 120 (to be described below) attached thereto, the vertical wire 160 may extend long enough to be in contact with the second chip pad 121 of the second semiconductor chip 120.

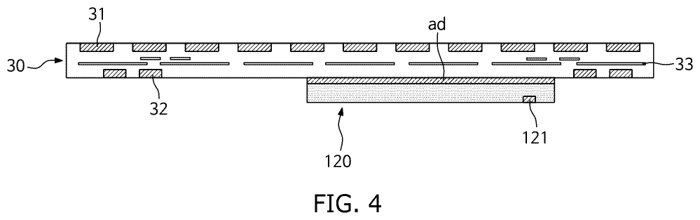

Referring to FIG. 4, the method for manufacturing the semiconductor package may include placing the second semiconductor chip 120 on the lower surface of the interposer substrate 30. The second semiconductor chip 120 may be disposed such that its front side on which the second chip pad 121 is formed may face in the opposite direction of the interposer substrate 30. That is, the second semiconductor chip 120 may be disposed such that its back side faces the interposer substrate 30.

The back side of the second semiconductor chip 120 may be attached to the lower surface of the interposer substrate 30 through an adhesive member (ad). The second semiconductor chip 120, which is attached through the adhesive member (ad), may not fall even if the lower surface of the interposer substrate 30 is positioned in the direction of gravity.

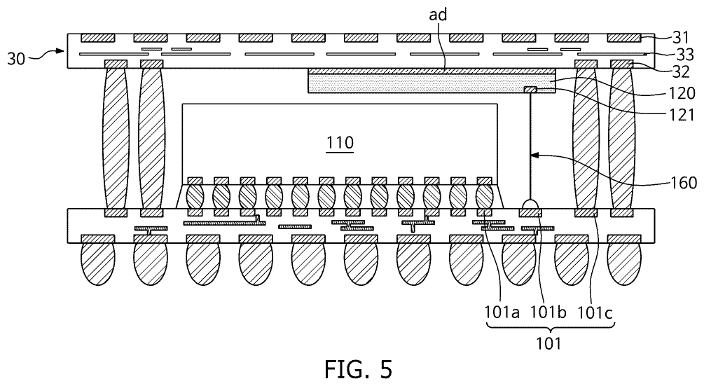

Referring to FIG. 5, the manufacturing the lower package 10 may include placing the interposer substrate 30 with the second semiconductor chip 120 attached thereto on the vertical connection member 150.

The interposer substrate 30 may be disposed such that the lower pad 32 of the interposer substrate 30 corresponds to an upper end of the vertical connection member 150. As the vertical connection member 150 and the lower pad 32 of the interposer substrate 30 are connected, the interposer substrate 30 and the lower package substrate 100 may be electrically connected.

The second semiconductor chip 120 attached to the lower surface of the interposer substrate 30 may be connected to an upper end of the vertical wire 160. The second chip pad 121 of the second semiconductor chip 120 may be in contact with the upper end of the vertical wire 160. The second semiconductor chip 120 may transmit and receive signals to and from the lower package substrate 100 through the vertical wire 160 without passing through the interposer substrate 30. That is, since the second semiconductor chip 120 is connected through the vertical wire 160, a signal transmission distance from the lower package substrate 100 may be shortened.

Referring to FIG. 6, the manufacturing the lower package 10 may include forming the lower mold layer 140 between the lower package substrate 100 and the interposer substrate 30.

The lower mold layer 140 may be on and at least partially cover the first semiconductor chip 110, the solder bump 152, the second semiconductor chip 120, the vertical connection member 150, and the vertical wire 160. Specifically, the lower mold layer 140 may cover all of the upper surface of the lower package substrate 100, side surfaces of the underfill 141, side surfaces of the first semiconductor chip 110, the lower surface and side surfaces of the second semiconductor chip 120, side surfaces of the vertical connection member 150, the vertical wire 160, etc.

The lower mold layer 140 may be formed of an epoxy molding compound (EMC). However, this is only an example, and the lower mold layer 140 may include various materials such as epoxy-based materials, thermosetting materials, thermoplastic materials, UV-treated materials, etc.

The lower mold layer 140 may be formed without involving forming the underfill 141. That is, if the underfill 141 is formed by MUF, the underfill 141 may be formed while forming the lower mold layer 140.

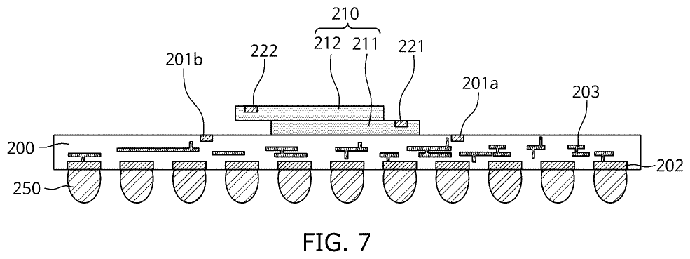

Referring to FIGS. 7 to 9, the method for manufacturing the semiconductor package may include manufacturing the upper package 20.

Referring to FIG. 7, the manufacturing the upper package 20 may include placing the upper semiconductor chip 210 on the upper package substrate 200. The upper semiconductor chip 210 may be disposed such that its front side on which the upper chip pad 221 is formed may face away from the upper package substrate 200. The upper semiconductor chip 210 may be disposed such that its back side faces the upper package substrate 200. The back side of the upper semiconductor chip 210 may be attached to the upper package substrate 200 by an adhesive member.

The plurality of upper semiconductor chips 210 may be provided. The plurality of upper semiconductor chips 211 and 212 may include the first upper semiconductor chip 211 and the second upper semiconductor chip 212. The second upper semiconductor chip 212 may be offset-stacked on the first upper semiconductor chip 211. The first upper semiconductor chip 211 and the second upper semiconductor chip 212 may each be disposed such that the first upper chip pad 221 and the second upper chip pad 222 are at least partially exposed. The second upper semiconductor chip 212 may be disposed to overlap at least a portion of the first upper semiconductor chip 211. That is, the first upper chip pad 221 may be disposed not to be covered by the second upper semiconductor chip 212 or may be free of the second upper semiconductor chip 212.

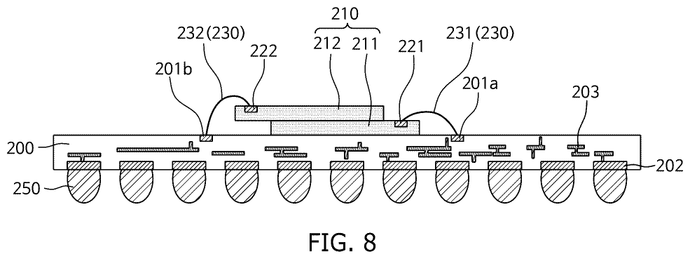

Referring to FIG. 8, the manufacturing the upper package 20 may include electrically connecting the upper semiconductor chip 210 to the upper package substrate 200. The upper semiconductor chip 210 may be connected to the upper package substrate 200 through wire bonding.

The upper wires 231 and 232 may each be connected to the upper chip pads 221 and 222. Specifically, the first upper wire 231 and the second upper wire 232 may each be connected to the first upper pad 201a and the second upper pad 201b of the upper package substrate 200. That is, the first upper chip pad 221 and the second upper chip pad 222 may each be electrically connected to the first upper pad 201a and the second upper pad 201b of the upper package substrate 200 by the upper wires 231 and 232.

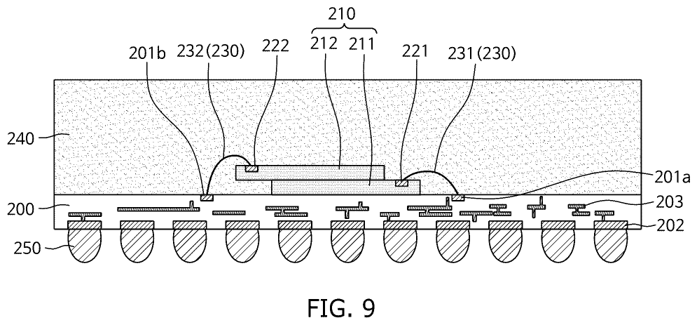

Referring to FIG. 9, the manufacturing the upper package 20 may include forming the upper mold layer 240 on the upper package substrate 200.

The upper mold layer 240 may be on and at least partially cover the upper semiconductor chips 211 and 212 and the upper wires 231 and 232. Specifically, the upper mold layer 240 may cover all of the upper surface of the upper package substrate 200, side surfaces, upper surface, and lower surface of the upper semiconductor chips 211 and 212, the upper wires 231 and 232, etc.

By placing the upper package 20 on the lower package 10, the semiconductor package 1 may be manufactured. In this case, the upper package 20 may be disposed such that the connection terminal 250 is connected to the upper pad 31 of the interposer substrate 30.

The semiconductor package according to another aspect will be described. The same or similar configurations as those already described above will be given the same reference numerals, and detailed description thereof may be omitted.

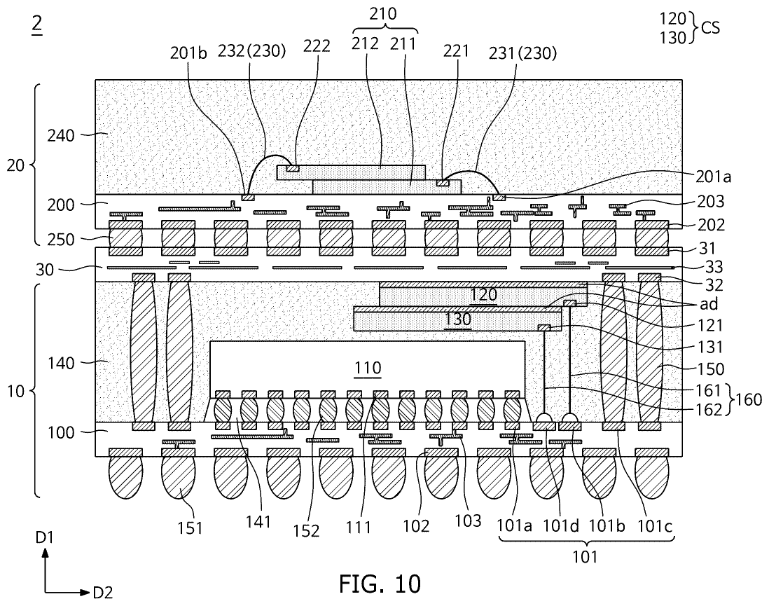

FIG. 10 is a diagram illustrating a semiconductor package.

Referring to FIG. 10, a semiconductor package 2 according to some aspects of the present disclosure may include the lower package 10 including a chip stack CS.

The lower package 10 may include the lower package substrate 100 including a plurality of upper pads 101b and 101d for electrically connecting the chip stack CS.

The lower package 10 may include the chip stack CS disposed on the lower surface of the interposer substrate 30. The chip stack CS may include the second semiconductor chip 120 disposed on the lower surface of the interposer substrate 30 and a third semiconductor chip 130 disposed on the lower surface of the second semiconductor chip 120.

The third semiconductor chip 130 may be disposed such that its front side on which a third chip pad 131 is formed faces the lower package substrate 100. The third semiconductor chip 130 may be disposed to at least partially expose the second chip pad 121 of the second semiconductor chip 120. The third semiconductor chip 130 may be disposed on the front side of the second semiconductor chip 120 not to overlap the second chip pad 121. That is, the third semiconductor chip 130 may be disposed on the front side of the second semiconductor chip 120 to at least partially expose the second chip pad 121. The third semiconductor chip 130 may be offset-stacked on the second semiconductor chip 120.

The third semiconductor chip 130 may be spaced upward from the first semiconductor chip 110. That is, the third semiconductor chip 130 may be spaced apart from the first semiconductor chip 110 in the first direction D1. A portion of the lower mold layer 140 may be disposed between the third semiconductor chip 130 and the first semiconductor chip 110. Since the third semiconductor chip 130 is spaced upward from the first semiconductor chip 110, damages due to excessive heat transfer and friction from the first semiconductor chip 110 may be prevented.

The third semiconductor chip 130 may be electrically connected to the lower package substrate 100. The third semiconductor chip 130 of FIG. 10 may be electrically connected to the lower package substrate 100 through a vertical wire.

The lower package 10 may include a first vertical wire 161 electrically connecting the second semiconductor chip 120 and the lower package substrate 100, and a second vertical wire 162 electrically connecting the third semiconductor chip 130 and the lower package substrate 100. The first vertical wire 161 and the second vertical wire 162 may extend in the first direction D1. That is, the first vertical wire 161 and the second vertical wire 162 may extend parallel to each other.

The third semiconductor chip 130 may be disposed to overlap at least a portion of the second semiconductor chip 120. The third semiconductor chip 130 may be offset and disposed so that the second chip pad 121 of the second semiconductor chip 120 is at least partially exposed. In order for the first vertical wire 161 to vertically connect the second chip pad 121 and the second upper pad 101b of the lower package substrate 100, it is necessary that interference with the third semiconductor chip 130 does not occur. Accordingly, the third semiconductor chip 130 may be disposed to overlap at least a portion of the second semiconductor chip 120 but may be disposed so that the second chip pad 121 is not covered or is free of the semiconductor chip 130.

The third semiconductor chip 130 may be disposed to overlap at least a portion of the first semiconductor chip 110. The third chip pad 131 of the third semiconductor chip 130 may be disposed to be at least partially exposed toward the lower package substrate 100. In order for the second vertical wire 162 to vertically connect the third chip pad 131 and the fourth upper pad 101d of the lower package substrate 100, it is necessary that interference with the first semiconductor chip 110 does not occur. Therefore, the third semiconductor chip 130 may be disposed to overlap at least a portion of the first semiconductor chip 110, but the third chip pad 131 may not overlap the first semiconductor chip 110 in the first direction D1.

The first vertical wire 161 may connect the second chip pad 121 and the second upper pad 101b of the lower package substrate 100 in the vertical direction. The second chip pad 121 and the second upper pad 101b may be aligned in the first direction D1. The second vertical wire 162 may vertically connect the third chip pad 131 and the fourth upper pad 101d of the lower package substrate 100. The third chip pad 131 and the fourth upper pad 101d may be aligned in the first direction D1.

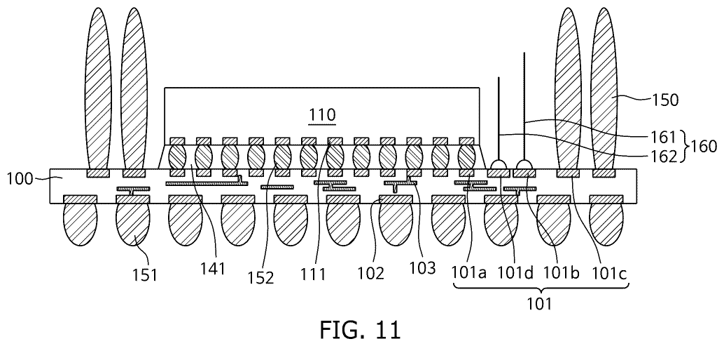

FIGS. 11 to 14 are diagrams illustrating a method for manufacturing a semiconductor package according to some aspects of the present disclosure.

A method for manufacturing the lower package 10 of the semiconductor package 2 of FIG. 10 will be described with reference to FIGS. 11 to 14. The description of the upper package 20 of the semiconductor package 1 of FIG. 1 may be the same as that of the upper package 20 of the semiconductor package 2.

Referring to FIG. 11, the method for manufacturing the semiconductor package according to some aspects of the present disclosure may include forming the first vertical wire 161 and the second vertical wire 162 on the lower package substrate 100. The first vertical wire 161 and the second vertical wire 162 may be disposed on one side of the first semiconductor chip 110.

The first vertical wire 161 and the second vertical wire 162 may extend along the first direction D1. The first vertical wire 161 and the second vertical wire 162 may have different lengths. Although FIG. 11 shows that the first vertical wire 161 extends longer than the second vertical wire 162, aspects are not limited thereto.

The first vertical wire 161 and the second vertical wire 162 may each be formed on the second upper pad 101b and the fourth upper pad 101d of the lower package substrate 100. The second upper pad 101b and the fourth upper pad 101d of the lower package substrate 100 may each be formed on one side of the first upper pads 101a.

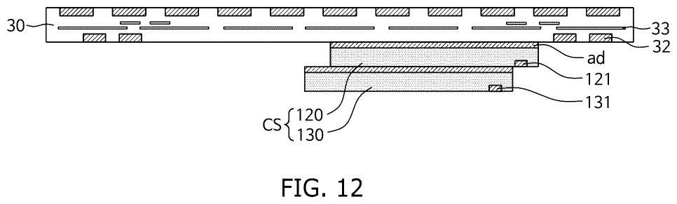

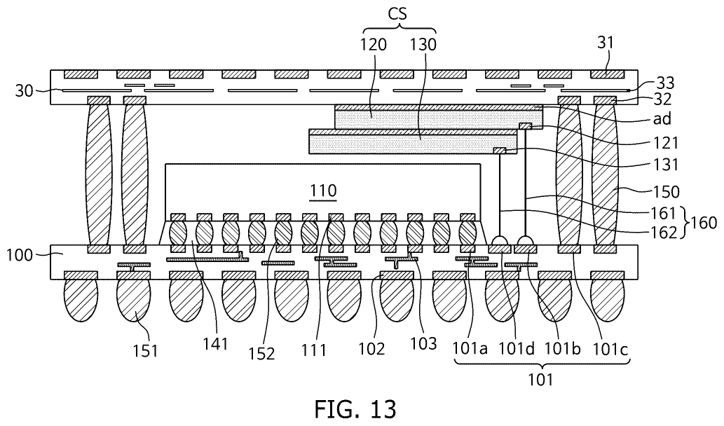

Referring to FIGS. 12 and 13, the method for manufacturing the semiconductor package according to some embodiments of the present disclosure may include placing the chip stack CS on the lower surface of the interposer substrate 30. The interposer substrate 30 with the chip stack CS disposed thereon may be disposed on the vertical connection member 150. The lower pad 32 of the interposer substrate 30 may be connected to the vertical connection member 150.

The chip stack CS may include the second semiconductor chip 120 disposed on the lower surface of the interposer substrate 30 and the third semiconductor chip 130 stacked on the lower surface of the second semiconductor chip 120. Although the chip stack CS is illustrated as including two semiconductor chips, it may include three or more semiconductor chips. Each of the second semiconductor chip 120 and the third semiconductor chip 130 may be disposed such that each of the front sides on which the second chip pad 121 and the third chip pad 131 is formed face the lower package substrate 100.

The second semiconductor chip 120 may be attached to the lower surface of the interposer substrate 30 by the adhesive member (ad). The third semiconductor chip 130 may be attached to the lower surface of the second semiconductor chip 120 by the adhesive member (ad).

The third semiconductor chip 130 may be offset and stacked on the lower surface of the second semiconductor chip 120. The third semiconductor chip 130 may be disposed to at least partially expose the second chip pad 121 of the second semiconductor chip 120. In other words, the second chip pad 121 of the second semiconductor chip 120 may be at least partially exposed toward the lower package substrate 100.

The second chip pad 121 of the second semiconductor chip 120 may be disposed to correspond to the second upper pad 101b of the lower package substrate 100. Likewise, the third chip pad 131 of the third semiconductor chip 130 may be disposed to correspond to the fourth upper pad 101d of the lower package substrate 100. In other words, each of the second chip pad 121 and the third chip pad 131 may be aligned with the second upper pad 101b and the fourth upper pad 101d in the first direction D1.

As such, when each of the second semiconductor chip 120 and the third semiconductor chip 130 is attached onto the interposer substrate 30 and the second semiconductor chip 120, they may be attached to correspond in position to the second chip pad 121 and the third chip pad 131.

Since the first vertical wire 161 and the second vertical wire 162 extending in the first direction D1 are each disposed on the second upper pad 101b and the fourth upper pad 101d, the second chip pad 121 and the third chip pad 131 may be in contact with the first vertical wire 161 and the second vertical wire 162, respectively.

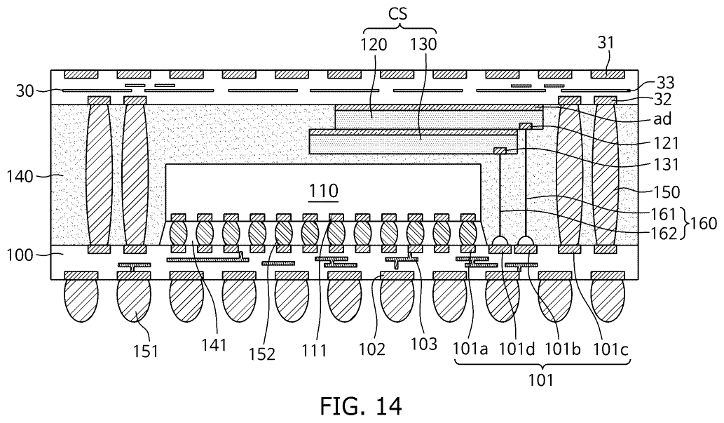

Referring to FIG. 14, the method for manufacturing the semiconductor package according to some embodiments of the present disclosure may include forming the lower mold layer 140 between the lower package substrate 100 and the interposer substrate 30.

The lower mold layer 140 may be on and at least partially cover the first semiconductor chip 110, the solder bump 152, the second semiconductor chip 120, the vertical connection member 150, the first vertical wire 161, and the second vertical wire 162. Specifically, the lower mold layer 140 may cover all of the upper surface of the lower package substrate 100, side surfaces of the underfill 141, side surfaces of the first semiconductor chip 110, the lower surface and side surfaces of the second semiconductor chip 120, side surfaces of the vertical connection member 150, the first vertical wire 161, the second vertical wire 162, etc.

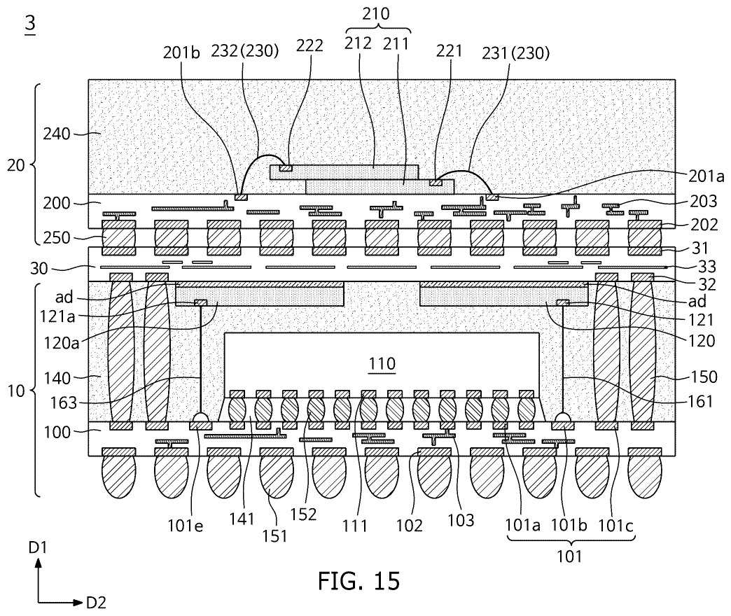

FIG. 15 is a diagram illustrating a semiconductor package according to some embodiments of the present disclosure.

Referring to FIG. 15, the semiconductor package 3 according to some embodiments of the present disclosure may include a fourth semiconductor chip 120a disposed at the same level as the second semiconductor chip 120. That is, the fourth semiconductor chip 120a may be disposed on the lower surface of the interposer substrate 30. In addition, the fourth semiconductor chip 120a may be disposed to be spaced upward from the first semiconductor chip 110.

The fourth semiconductor chip 120a may be disposed to be spaced apart from the second semiconductor chip 120 in the second direction D2 parallel to the upper surface of the lower package substrate 100. The fourth semiconductor chip 120a may be located opposite the second semiconductor chip 120 in the second direction D2 with respect to the first semiconductor chip 110.

The fourth semiconductor chip 120a may be disposed such that at least a portion of the fourth semiconductor chip 120a overlaps the first semiconductor chip 110. The fourth semiconductor chip pad 121a may be disposed not to overlap the first semiconductor chip 110 in the first direction D1. The fourth semiconductor chip 120a may be disposed such that a lower surface of the fourth chip pad 121a is at least partially exposed toward the lower package substrate 100. The fourth chip pad 121a may be disposed to correspond to a fifth upper pad 101e of the lower package substrate 100.

The lower package 10 may include a third vertical wire 163 electrically connecting the fourth semiconductor chip 120a and the lower package substrate 100. The third vertical wire 163 may extend in the first direction D1. The third vertical wire 163 may electrically connect the fourth chip pad 121a of the fourth semiconductor chip 120a and the fifth upper pad 101e of the lower package substrate 100.

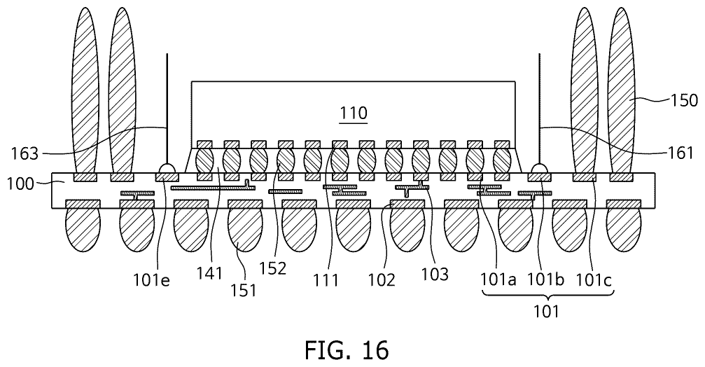

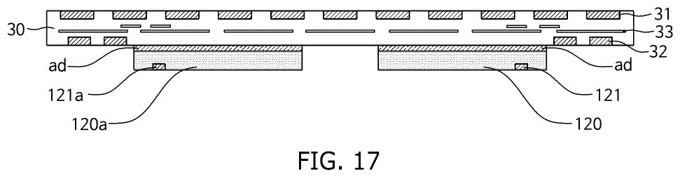

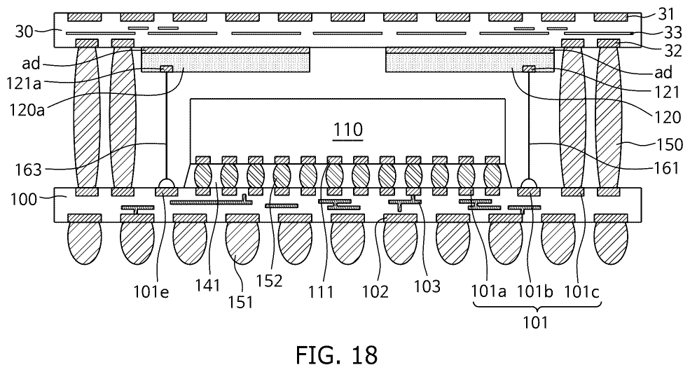

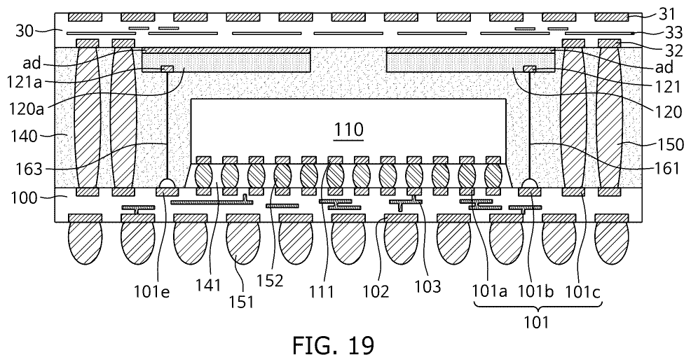

FIGS. 16 to 19 are diagrams illustrating a method for manufacturing a semiconductor package according to some embodiments of the present disclosure.

Referring to FIGS. 16 to 19, the method for manufacturing the semiconductor package according to some embodiments of the present disclosure may include forming the first vertical wire 161 and the third vertical wire 163 on the lower package substrate 100. The first vertical wire 161 and the third vertical wire 163 may each be disposed on one side and the other side of the first semiconductor chip 110.

The first vertical wire 161 and the third vertical wire 163 may extend along the first direction D1. The first vertical wire 161 and the third vertical wire 163 may each be formed on the second upper pad 101b and the fifth upper pad 101e of the lower package substrate 100. The second upper pad 101b and the fifth upper pad 101e of the lower package substrate 100 may each be formed on one and the other side in the second direction D2 with respect to the first semiconductor chip 110.

The second semiconductor chip 120 and the fourth semiconductor chip 120a may be disposed on the lower surface of the interposer substrate 30. The interposer substrate 30 with the second semiconductor chip 120 and the fourth semiconductor chip 120a disposed thereon may be disposed on the vertical connection member 150. The lower pad 32 of the interposer substrate 30 may be connected to the vertical connection member 150.

Each of the second semiconductor chip 120 and the fourth semiconductor chip 120a may be disposed such that each of the front sides on which the second chip pad 121 and the fourth chip pad 121a is formed face the lower package substrate 100.

The second semiconductor chip 120 and the fourth semiconductor chip 120a may be attached to the lower surface of the interposer substrate 30 by the adhesive member (ad). Each of the second semiconductor chip 120 and the fourth semiconductor chip 120a may be disposed such that at least a portion of the second semiconductor chip 120 and the fourth semiconductor chip 120a overlaps the first semiconductor chip 110.

The second chip pad 121 of the second semiconductor chip 120 may be disposed to correspond to the second upper pad 101b of the lower package substrate 100. Likewise, the fourth chip pad 121a of the fourth semiconductor chip 120a may be disposed to correspond to the fifth upper pad 101e of the lower package substrate 100. In other words, each of the second chip pad 121 and the fourth chip pad 121a may be aligned with the second upper pad 101b and the fifth upper pad 101e along the first direction D1.

Since the first vertical wire 161 and the third vertical wire 163 extending in the first direction D1 are each disposed on the second upper pad 101b and the fifth upper pad 101e, the second chip pad 121a and the fourth chip pad 121a may be in contact with the first vertical wire 161 and the third vertical wire 163, respectively.

The method for manufacturing the semiconductor package according to some aspects of the present disclosure may include forming the lower mold layer 140 between the lower package substrate 100 and the interposer substrate 30.

The lower mold layer 140 may be on and at least partially cover the first semiconductor chip 110, the solder bump 152, the second semiconductor chip 120, the fourth semiconductor chip 120a, the vertical connection member 150, the first vertical wire 161, and the third vertical wire 163. Specifically, the lower mold layer 140 may cover all of the upper surface of the lower package substrate 100, side surfaces of the underfill 141, side surfaces of the first semiconductor chip 110, the lower surface and side surfaces of the second semiconductor chip 120, the lower surface and side surfaces of the fourth semiconductor chip 120a, side surfaces of the vertical connection member 150, the first vertical wire 161, the third vertical wire 163, etc.

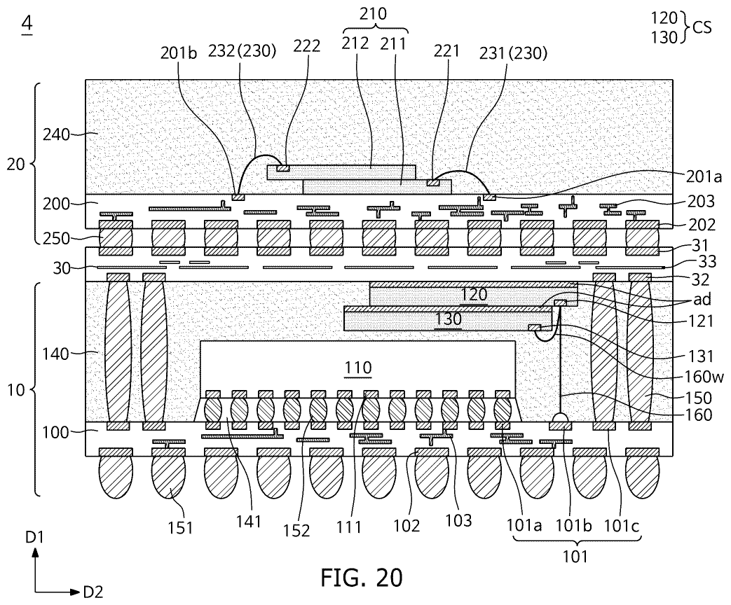

FIG. 20 is a diagram illustrating a semiconductor package according to some embodiments of the present disclosure.

Referring to FIG. 20, a semiconductor package 4 according to some embodiments of the present disclosure may include the lower package 10 including the chip stack CS.

The chip stack CS may include the second semiconductor chip 120 disposed on the lower surface of the interposer substrate 30 and a third semiconductor chip 130 disposed on the lower surface of the second semiconductor chip 120. The second semiconductor chip 120 and the third semiconductor chip 130 may each be electrically connected to the lower package substrate 100.

The second semiconductor chip 120 may be electrically connected to the lower package substrate 100 through the vertical wire 160. The vertical wire 160 may connect the second chip pad 121 of the second semiconductor chip 120 and the second chip pad 101b of the lower package substrate 100 in the first direction D1.

The third semiconductor chip 130 of FIG. 20 may be electrically connected to the second semiconductor chip 120 through a bonding wire 160w. The bonding wire 160w may connect the second chip pad 121 and the third chip pad 131. The bonding wire 160w may be formed by a wire bonding process. That is, the third semiconductor chip 130 may be connected to the second semiconductor chip 120 through the bonding wire 160w connected to the third chip pad 131 and may be electrically connected to the lower package substrate 100 through the vertical wire 160 connected to the second semiconductor chip 120.

The third chip pad 131 of the third semiconductor chip 130 may be disposed in the same direction as the direction in which the second chip pad 121 of the second semiconductor chip 120 is located. The second chip pad 121 and the third chip pad 131 may be positioned in the same direction so that the second chip pad 121 and the third chip pad 131 are connected by the bonding wire 160w. Specifically, the second chip pad 121 and the third chip pad 131 may each be located away from the first semiconductor chip 110 along the second direction D2.

According to the example shown in FIG. 20, the third semiconductor chip 130 and the second semiconductor chip 120 are connected through the bonding wire 160w, so that the materials used for the vertical wires for connecting the third semiconductor chip 130 and the lower package substrate 100 can be reduced.

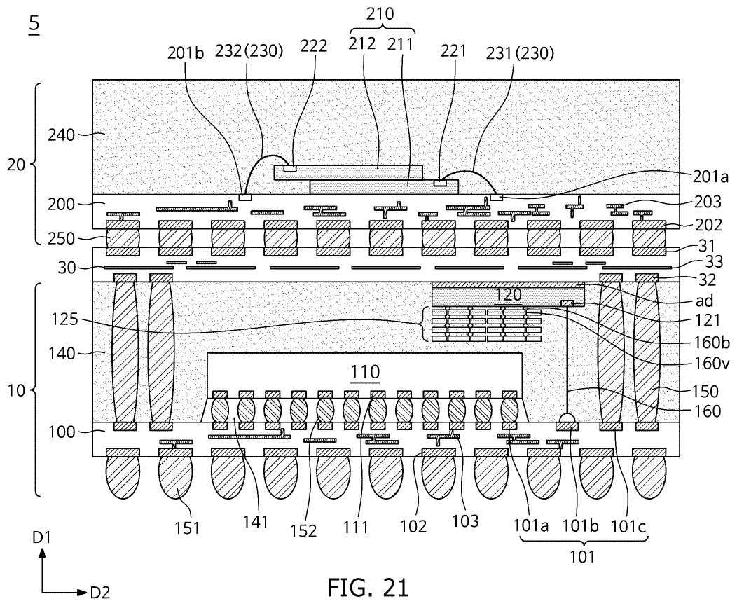

FIG. 21 is a diagram illustrating a semiconductor package according to some embodiments of the present disclosure.

Referring to FIG. 21, a semiconductor package 5 according to some embodiments of the present disclosure may include the lower package 10 including a fifth semiconductor chip 125.

The fifth semiconductor chip 125 may be a stacked memory device. The fifth semiconductor chip 125 may include the second semiconductor chip 120 disposed on the lower surface of the interposer substrate 30, and the fifth semiconductor chip 125 disposed on the lower surface of the second semiconductor chip 120. The second semiconductor chip 120 and the fifth semiconductor chip 125 may each be electrically connected to the lower package substrate 100.

The fifth semiconductor chip 125 may be disposed such that at least a portion of the first semiconductor chip 125 overlaps the first semiconductor chip 110. In addition, the fifth semiconductor chip 125 may be disposed to be spaced upward from the first semiconductor chip 110.

The fifth semiconductor chip 125 of FIG. 21 may include a plurality of memory chips. The plurality of memory chips may be electrically connected through the bumps 160b and through vias (TSVs) 160v. In addition, the fifth semiconductor chip 125 and the second semiconductor chip 120 may be electrically connected through the bumps 160b and the through vias 160v.

A plurality of memory chips forming the fifth semiconductor chip 125 may be electrically connected to the second semiconductor chip 120 through the through vias 160v and the bumps 160b. The plurality of memory chips may transmit and receive signals to and from the second semiconductor chip 120 through the through vias 160v and the bumps 160b.

In addition, the second semiconductor chip 120 may be electrically connected to the lower package substrate 100 through the vertical wire 160. The plurality of memory chips of the fifth semiconductor chip 125 may be electrically connected to the lower package substrate 100 through the vertical wire 160 connected to the second semiconductor chip 120.

The first semiconductor chip 110 may execute applications supported by the semiconductor package 1 using the second semiconductor chip 120 and the fifth semiconductor chip 125. For example, the first semiconductor chip 110 may perform operations specialized in at least one of a central processing unit (CPU), an application processor (AP), a graphic processing unit (GPU), a neural processing unit (NPU), a modem (TPU), a tensor processing unit (TPU), a vision processing unit (VPU), an Image signal processor (ISP), and a digital signal processor (DSP).

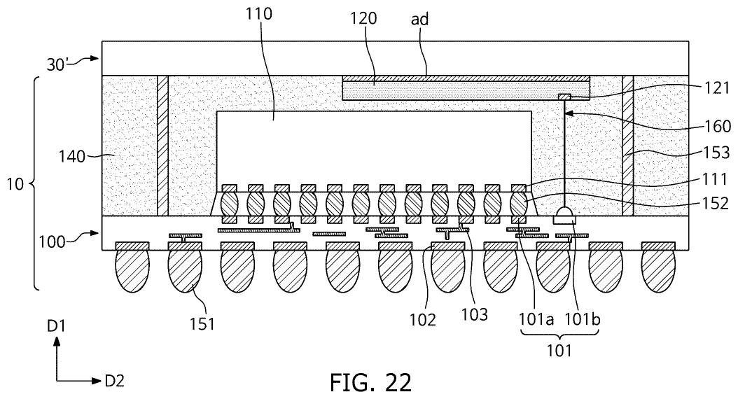

FIG. 22 is a diagram illustrating a semiconductor package according to some embodiments of the present disclosure.

Referring to FIG. 22, a semiconductor package according to some aspects of the present disclosure may include a substrate and a supporter 153 supporting the substrate. The semiconductor package according to an embodiment of the present disclosure may not include an upper package. Accordingly, the substrate may be a plate 30′ on which no wiring pattern, etc. is formed. However, embodiments are not limited thereto, and the substrate may include the interposer substrate 30, a printed circuit board (not illustrated), etc.

The plate 30′ may be disposed on the lower package 10. The plate 30′ may be disposed on the upper surface of the lower package 10. The plate 30′ may be disposed on the lower mold layer 140. The plate 30′ may be spaced apart from the lower package substrate 100 in the second direction D2.

The supporter 153 may be provided on the lower package substrate 100. The supporter 153 may be disposed on one side of the first semiconductor chip 110. The supporters 153 may be disposed on both sides of the first semiconductor chip 110.

The supporter 153 may support the plate 30′. The supporter 153 may extend in the second direction D2 on the lower package substrate 100. The supporter 153 may extend in parallel with the vertical wire 160. For example, the supporter 153 may have a bar shape extending in the second direction D2. However, the shape of the supporter 153 is not limited thereto. A lower end of the supporter 153 may contact the lower package substrate 100, and an upper end of the supporter 153 may contact the plate 30′. The supporter 153 may support the plate 30′ such that the plate 30′ is spaced apart from the lower package substrate 100 in the first direction D1.

The second semiconductor chip 120 may be disposed on a lower surface of the plate 30′. The second semiconductor chip 120 may be spaced apart from the first semiconductor chip 110 in the first direction D1. The supporter 153 may support the plate 30′ with the second semiconductor chip 120 disposed on the lower surface of the plate 30′. The first semiconductor chip 110 may be disposed on the upper surface of the lower package substrate 100. The second semiconductor chip 120 disposed on the lower surface of the plate 30′ and the first semiconductor chip 110 disposed on the upper surface of the lower package substrate 100 may be spaced apart from each other in the first direction D1. That is, the second semiconductor chip 120 may be spaced upward from the first semiconductor chip 110.

The plate 30′ may dissipate heat generated from the lower package 10 to the outside of the lower package 10. For example, the heat generated from the first semiconductor chip 110 or the second semiconductor chip 120 of the lower package 10 may be dissipated through the plate 30′. A metal material may be included to improve heat dissipation performance of the plate 30′.

While example embodiments have been shown and described above, it will be apparent to those skilled in the art that modifications and variations could be made without departing from the scope of the present inventive concept as defined by the appended claims.

1. A semiconductor package, comprising:
a lower package; and
a substrate on the lower package,
wherein the lower package comprises:
a lower package substrate;
a first semiconductor chip on the lower package substrate such that a front side of the first semiconductor chip on which a first chip pad is formed faces the lower package substrate;
a second semiconductor chip on a lower surface of the substrate spaced apart from the first semiconductor chip in a first direction perpendicular to an upper surface of the lower package substrate; and
a vertical wire connecting the lower package substrate and the second semiconductor chip in the first direction.

2. The semiconductor package according to claim 1, wherein at least a portion of the second semiconductor chip overlaps the first semiconductor chip in the first direction.

3. The semiconductor package according to claim 1, wherein the second semiconductor chip is arranged such that a front side of the second semiconductor chip on which a second chip pad is formed faces the lower package substrate, and
wherein the second chip pad does not overlap the first semiconductor chip in the first direction.

4. The semiconductor package according to claim 3, wherein the lower package further comprises a solder bump electrically connecting the first chip pad and the lower package substrate,
wherein the lower package substrate comprises a first upper pad connected to the solder bump and a second upper pad connected to the vertical wire, and
wherein the second upper pad is aligned with the second chip pad in the first direction.

5. The semiconductor package according to claim 3, wherein the lower package further includes a third semiconductor chip on the front side of the second semiconductor chip arranged not to overlap the second chip pad and spaced apart from the first semiconductor chip in the first direction, and
wherein the third semiconductor chip is electrically connected to the lower package substrate.

6. The semiconductor package according to claim 5, wherein the vertical wire is a first vertical wire,
wherein the third semiconductor chip is arranged such that a front side of the third semiconductor chip on which a third chip pad is formed faces the lower package substrate,
wherein the third chip pad does not overlap the first semiconductor chip in the first direction, and
wherein the lower package further comprises a second vertical wire connecting the third chip pad and the lower package substrate in the first direction.

7. The semiconductor package according to claim 6, wherein the lower package substrate further includes a third upper pad electrically connected to the second vertical wire, and
the third upper pad is aligned with the third chip pad in the first direction.

8. The semiconductor package according to claim 5, wherein the lower package further comprises a bonding wire electrically connecting the second semiconductor chip and the third semiconductor chip.

9. The semiconductor package according to claim 5, wherein the lower package includes a through via electrically connected to the second semiconductor chip and extending through the third semiconductor chip.

10. The semiconductor package according to claim 1, wherein the lower package further comprises:
a fourth semiconductor chip aligned with the second semiconductor chip in the first direction and spaced apart from the second semiconductor chip in a second direction parallel to the upper surface of the lower package substrate; and
a third vertical wire connecting the fourth semiconductor chip and the lower package substrate in the first direction.

11. The semiconductor package according to claim 1, wherein
the substrate is an interposer substrate, and
the semiconductor package further includes an upper package on the interposer substrate, and
the upper package comprises:
an upper package substrate;
a connection terminal electrically connecting the upper package substrate and the interposer substrate;
an upper semiconductor chip on the upper package substrate; and
an upper mold layer on and at least partially covering the upper semiconductor chip on the upper package substrate.

12. The semiconductor package according to claim 1, wherein the substrate is an interposer substrate, and
wherein the lower package further includes:
a conductive post electrically connecting the lower package substrate and the interposer substrate between the lower package substrate and the interposer substrate; and
a lower mold layer on and at least partially covering the first semiconductor chip, the second semiconductor chip, and the vertical wire on the lower package substrate.

13. The semiconductor package according to claim 1, wherein the first semiconductor chip is a modem chip, and the second semiconductor chip is a memory chip.

14. A semiconductor package, comprising:
a lower package;
an upper package on the lower package; and
an interposer substrate between the lower package and the upper package, wherein
the lower package includes:
a lower package substrate;
a first semiconductor chip on the lower package substrate such that a front side of the first semiconductor chip on which a first chip pad is formed faces the lower package substrate;
a second semiconductor chip spaced upward from the first semiconductor chip such that a front side of the second semiconductor chip on which a second chip pad is formed faces the lower package substrate; and
a vertical wire extending in a vertical direction to electrically connect the lower package substrate and the second chip pad, and
the upper package includes:
an upper package substrate;
a connection terminal connecting the upper package substrate and the interposer substrate; and
an upper semiconductor chip electrically connected to the upper package substrate on the upper package substrate.

15. The semiconductor package according to claim 14, wherein a back side of the second semiconductor chip is attached to the interposer substrate by an adhesive member.

16. The semiconductor package according to claim 14, wherein the second semiconductor chip is offset from the first semiconductor chip in a horizontal direction such that the second chip pad corresponds to an upper pad of the lower package substrate in the vertical direction, the horizontal direction being perpendicular to the vertical direction.

17. The semiconductor package according to claim 14, wherein
the vertical wire is a first vertical wire, and
the lower package further includes:
a third semiconductor chip on the front side of the second semiconductor chip to at least partially expose the second chip pad such that a front side of the third semiconductor chip on which a third chip pad is formed thereon faces the lower package substrate; and
a second vertical wire connecting the third chip pad and the lower package substrate in the vertical direction.

18. The semiconductor package according to claim 17, wherein the third semiconductor chip is spaced apart from the first semiconductor chip in the vertical direction.

19. The semiconductor package according to claim 14, wherein the lower package further includes:
a fourth semiconductor chip aligned with the second semiconductor chip in the vertical direction and spaced apart from the second semiconductor chip in a horizontal direction, the horizontal direction being perpendicular to the vertical direction; and
a third vertical wire connecting the fourth semiconductor chip and the lower package substrate in the vertical direction.

20. A semiconductor package, comprising:
a lower package;
an upper package on the lower package; and
an interposer substrate between the lower package and the upper package, wherein
the lower package includes:
a lower package substrate;
a modem chip on the lower package substrate arranged such that a front side of the modem chip on which a modem chip pad is formed faces the lower package substrate;
a conductive post electrically connecting the lower package substrate and the interposer substrate on one side of the modem chip;
a solder bump electrically connecting the modem chip pad and the lower package substrate;
a volatile memory chip attached onto a lower surface of the interposer substrate such that a front side of the volatile memory chip on which a memory chip pad is formed faces the lower package substrate, and spaced apart from the modem chip in a vertical direction perpendicular to an upper surface of the lower package substrate;
a vertical wire extending in the vertical direction to electrically connect the lower package substrate and the memory chip pad; and
a lower mold layer at least partially covering the modem chip, the volatile memory chip, the conductive post, and the vertical wire on the lower package substrate, and
the upper package includes:
an upper package substrate;
a nonvolatile memory chip electrically connected to the upper package substrate on the upper package substrate; and
an upper mold layer at least partially covering the nonvolatile memory chip on the upper package substrate.
